(19) United States
(12) Patent Application Publication
(10) Pub. No.: US 2009/0224291 A1
(43) Pub. Date: Sep. 10, 2009

(54) Method for self aligned sharp and shallow doping depth profiles

(75) Inventor: Nils J. Knall, Sunnyvale, CA (US)

Correspondence Address: BAKER BOTTS L.L.P., 2001 ROSS AVENUE, SUITE 600, DALLAS, TX, 75201-2980, US

(73) Assignee: DSM Solutions, Inc.

(21) Appl. No.: 12/074,643

(22) Filed: Mar. 4, 2008

(51) Int. Cl. H01L 29/772; H01L 21/335

(52) U.S. Cl. 257/285; 438/527; 438/194; 257/E29.242; 257/E21.143; 257/E21.4

(57) ABSTRACT

A method for fabricating a semiconductor device comprises forming a channel of a transistor, wherein the channel has a first conductivity type. The method further comprises depositing a layer of dielectric on at least a portion of the channel. The method further comprises etching a notch in the layer of dielectric wherein at least a portion of the notch is etched at least to the channel. The method also comprises doping the portion of the channel in the notch with material of a second conductivity type. The method further comprises filling the notch with polysilicon.

### TECHNICAL FIELD

This disclosure relates in general to semiconductor manufacturing and more particularly to controlling a doping profile.

### OVERVIEW

Transistors and other semiconductor devices have become a fundamental building block for a wide range of electronic components. Metal-oxide semiconductor field effect transistors have been the primary choice for transistors in many applications including general use microprocessors, digital signal processors, application specific integrated circuits, and various other forms of electronic devices. With an increasing demand for electronic devices, the inclusion of an oxide layer creates significant limitations to further improvements in the size and the operating speed of such devices. Consequently, the focus of industry development has begun to shift to other types of semiconductor devices. These other devices also present unique challenges and obstacles for engineers and fabrication experts alike.

### SUMMARY OF EXAMPLE EMBODIMENTS

In accordance with one embodiment of the present disclosure, a method for fabricating a semiconductor device comprises forming a channel of a transistor, wherein the channel has a first conductivity type. The method further comprises depositing a layer of hard mask material, that could consist of an oxide or other dielectric material, on at least a portion of the channel. The method further comprises etching a notch in the hard mask layer wherein at least a portion of the notch is etched at least to the channel. The method also comprises doping a portion of the channel exposed by the notch with material of a second conductivity type. The method further comprises filling the notch with a first conductive material such as polysilicon or metal. The first conductive material could comprise a gate electrode.

In accordance with another embodiment, a method for fabricating a semiconductor device comprises forming a channel of a transistor, wherein the channel has a first conductivity type. The method further comprises depositing a layer of hard mask material, that could consist of an oxide or other dielectric material, on at least a portion of the channel. The method further comprises etching a first notch in the hard mask layer of wherein at least a portion of the first notch is etched at least to the channel. The method further comprises doping a portion of the channel exposed by the first notch with material of a second conductivity type. The method also comprises etching a second notch in the layer of oxide wherein at least a portion of the second notch is etched at least to the channel. The method further comprises doping the portion of the channel in the second notch. The method also comprises etching a third notch in the layer of oxide wherein at least a portion of the third notch is etched at least to the channel. The method further comprises doping the portion of the channel in the third notch. The method further comprises filling the first, the second, and the third notches with a first conductive material such as polysilicon or metal.

In accordance with another embodiment of the present disclosure, a method for fabricating a semiconductor device comprises forming a channel of a transistor, wherein the channel has a first conductivity type. The method further comprises depositing a layer of hard mask material, that could consist of an oxide or other dielectric material, on at least a portion of the channel. The method further comprises etching a notch in the hard mask layer wherein at least a portion of the notch is etched at least to the channel. The method also comprises doping a portion of the channel exposed by the notch with material of a second conductivity type. The method further comprises filling the notch with a first conductive material such as polysilicon or metal. The method further comprises removing a portion of the hardmask material surrounding the first conductive material, forming a spacer around a portion of the first conductive material and covering a portion of the channel, then doping a second portion of the channel that is not covered by the spacer or first conductive material, with material of a first conductivity type. The method further comprises depositing a second conductor over the second portion of the channel. The second conductor can consist of a metal that can be annealed to form a silicide over the second portion of the channel.

Important technical advantages of certain embodiments of the present disclosure include the ability to control the doping profile in the channel and the ability to self align the volume of the material of the second conductivity type with the gate electrode. Another advantage includes the ability to control the dimensions of the channel. Other technical advantages of the present disclosure will be readily apparent to one skilled in the art from the following figures, descriptions, and claims.

Moreover, while specific advantages have been enumerated above, various embodiments may include all, some, or none of the enumerated advantages.

### BRIEF DESCRIPTION OF THE DRAWINGS

FIG. 1A illustrates a cross-sectional view of a semiconductor device according to a particular embodiment of the present disclosure;

FIG. 1B illustrates a cross-sectional view of a semiconductor device according to a particular embodiment of the present disclosure;

FIG. 2 is a graph illustrating an example doping profile of a semiconductor device; and

FIGS. 3A-3E illustrate an example method of controlling a doping profile in a semiconductor device.

### DETAILED DESCRIPTION

The level of doping in a semiconductor device controls how the channel conducts electricity. As devices are made smaller for a variety of reasons (for example, to conserve power or to pack more devices into a given area), the width of the channel can also shrink, and thus it can become more difficult to control the level of doping that exists at a given depth in the channel (the doping profile). In particular, certain types of JFET devices may require precise control of the doping profile below the gate electrode.

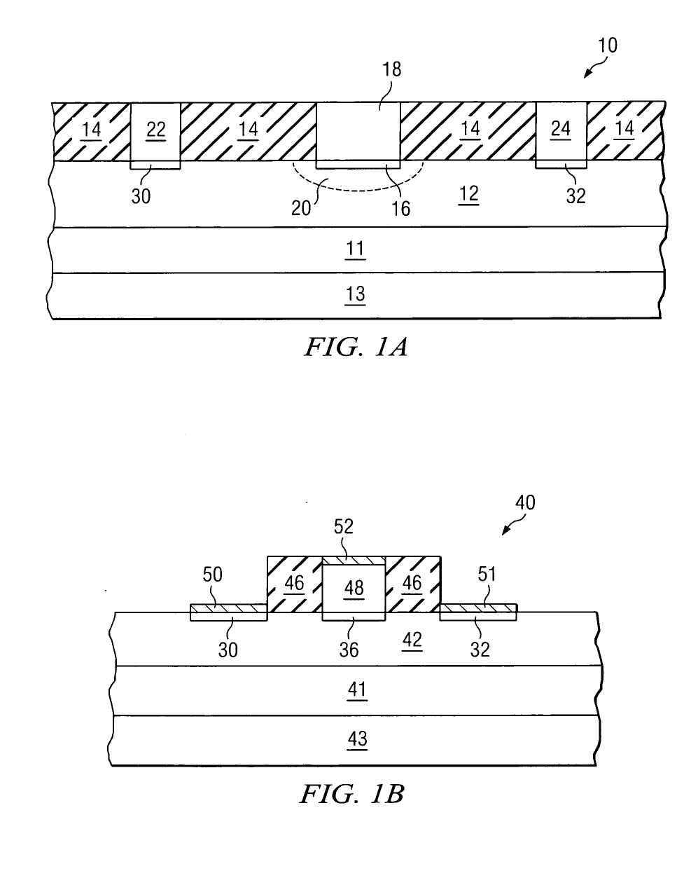

FIG. 1A illustrates an example of a semiconductor device 10 according to a particular embodiment of the present disclosure. FIG. 1A is illustrative only, and is not necessarily to scale. The components of FIG. 1A may also be arranged in other configurations and still fall within the scope of the disclosed embodiments. FIG. 1A illustrates semiconductor device 10 which comprises a semiconductor substrate 13 in which a channel 12 is formed. Channel 12 can be N-type or P-type. In this example, channel 12 is a P-type channel. P-channel 12 can be comprised of any semiconductor material to which dopants can be added to form various conductivity regions. For example, in a group 4 semiconductor like Silicon, a p-type doping region can be formed by adding a group 3 element like Boron, Gallium and/or Indium to that region. In the embodiment depicted in FIG. 1A the P-channel 12 provides a path to conduct current between a source region 22 and a drain region 24. In alternative embodiments, channel 12 may be an N-channel and may be doped by group 5 elements such as Antimony, Arsenic, Phosphorous, or any other appropriate N-type dopant. In certain embodiments, channel 12 can be doped to a concentration of 2.0×10¹⁵ atoms/cm³ to 1.0×10¹⁹ atoms/cm³. In some embodiments, channel 12 may be formed by epitaxial growth of silicon or silicon alloys. When using epitaxial growth the doping may be introduced during the growth process allowing for precise control of the doping profile and dimensions of the channel. In other embodiments ion implantation may be used to dope the channel. Semiconductor device 10 may further comprise a well 11 that can provide isolation between devices in combination with a shallow-trench isolation (STI) structure.

Semiconductor device 10 also comprises a dielectric layer 14 deposited on top of channel 12. The dielectric layer can consist of, for example, oxide or nitride that can be deposited or grown on channel 12 using any suitable method. As one example, dielectric layer 14 can be deposited using high density plasma deposition.

After dielectric layer 14 has been placed on channel 12, a notch 18 can be etched in dielectric layer 14. In certain embodiments, notch 18 can comprise the location of a gate of a junction field effect transistor (“JFET”). Dielectric layer 14 can be etched all the way down to P-channel 12. P-channel 12 can then be doped with a material of a different conductivity type than the conductivity of P-channel 12. This doping can be done with the use of ion implantation. Semiconductor device 10 comprises doped area 16 which has been doped by ion implantation with an N-type material implanted in P-channel 12. In certain embodiments, the sharpness, concentration, and depth of doped area 16 can be controlled. By controlling the depth and concentration of the doping in doped area 16, the depth of P-channel 12 and the P-doping level of P-channel 12 may also be controlled. This can be useful, for example, in certain small low-power JFET devices that utilize thin channels. After doping has been implanted in doped area 16, notch 18 can be filled with polysilicon or metal. During deposition of polysilicon or metal in notch 18, polysilicon or metal may accumulate over the oxide. This excess can be removed by a chemical mechanical planarization process. When polysilicon is used, it can be N-doped to improve conductivity. The conductor 18 in combination with region 16 can form the gate of a JFET.

Dashed area 20 shows a possible concentration of N-type doping when diffusion through polysilicon is used, instead of ion implantation, to create a gate of a transistor. The dimensions and doping concentration of dashed area 20 may be difficult to control when doping is performed by using diffusion through polysilicon. Doped area 16, in contrast, may be created with sharp edges and a shallow width in P-channel 12 through the use of ion implantation. The ability to control the width of doped area 16 allows the doping profile of P-channel 12 to also be controlled, which can lead to more accurate manufacturing of semiconductor devices.

In certain embodiments, a source 22 and/or a drain contact 24 of a transistor can also be created. Any suitable method can be used to create source contact 22 and drain contact 24. As one example, notches can be etched in dielectric layer 14. These notches can then be filled with polysilicon and the polysilicon can be doped by ion implantation. By choosing an implant energy that is high enough, source region 30 and drain region 32 can be doped by the ions penetrating through the polysilicon. In an alternative embodiment, source contact 22 and drain contact 24 may be created by filling the notches with metal. Ion implantation can be used to dope regions 30 and 32 prior to metal deposition. As yet another example, dielectric layer 14 can be completely stripped away before source contact 22 and drain contact 24 are created.

A semiconductor device 40 that can be formed using this procedure is depicted in FIG. 1B. This procedure can involve forming an insulating spacer 46 around the poly gate 48, implanting source 30 and drain 32 regions with the same doping type as the channel 42, and forming one or more silicide contacts 50, 51, and 52 on the exposed silicon of source and drain regions 30 and 32 and/or over the polysilicon gate 48. Semiconductor device 40 may also comprise a well 41 and a substrate 43.

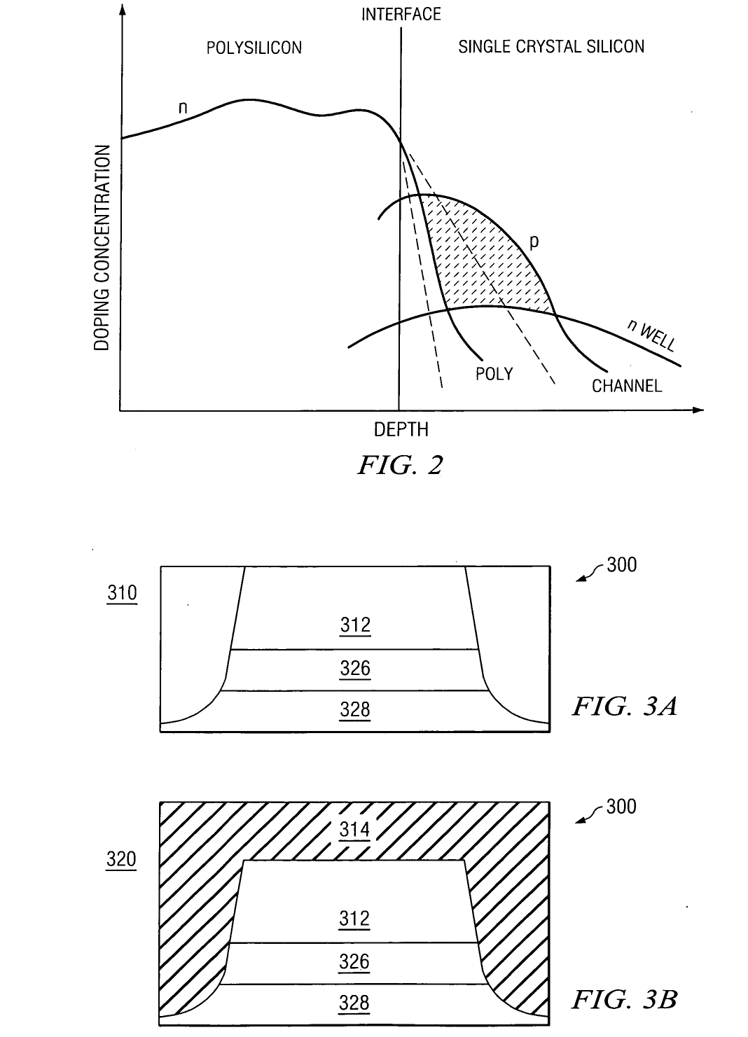

FIG. 2 is a graph illustrating an example doping profile of semiconductor device 10. The graph is not necessarily to scale, and is only intended as one possible example of a doping profile. The vertical axis of the graph in FIG. 2 illustrates the doping concentration of the semiconductor material. A higher level on the graph indicates a higher concentration of doping, whether N-type doping or P-type doping. The horizontal axis shows the depth of the semiconductor material. The left half of the graph represents the polysilicon material. In this example, the polysilicon material has been doped with an N-type dopant, and the solid curved line labeled “poly” on the graph depicts the concentration of N-type doping at varying depths of the semiconductor material. As the depth on the graph increases from left to right, the N-type polysilicon material meets the single crystal silicon material. This intersection is labeled “interface,” and is depicted with a vertical line near the center of the graph. As one example, the single crystal silicon section could comprise a channel of a transistor. Near the interface between the polysilicon material and the single crystal silicon material, the N-type doping concentration begins to fall. The N-type doping concentration to the right of the interface is the amount of doping that has been implanted or diffused into the single crystal silicon.

A second solid curved line on the graph depicts the doping concentration of the P-type doping, which mostly resides within the single crystal silicon in this example. This curve is labeled “channel” and represents the P-type doping in the channel region of the semiconductor material. A third curved line is labeled “well” and represents the N-type doping of the well used in this example. The total level of doping at any point in the semiconductor material is P-N; that is, the difference between the P-type and N-type doping levels. As depicted in FIG. 2, the shaded area on the graph shows the total level of doping in the channel. The width of this area represents the depth of the channel region. For example, if this area is very wide the depth of the channel in the single crystal silicon will also be very wide. If this area is narrow, the depth of the channel will correspondingly also be narrow. The width of this area can vary due to the different paths taken by the solid lines representing doping levels through the semiconductor materials. That is, the N-type doping level represented by the line labeled “poly” can follow one of a number of paths once it crosses the interface into the single crystal silicon. Two of these possible alternative paths are shown in FIG. 2, represented by dashed lines running through the single crystal silicon. A P-type doping concentration (the shaded area in FIG. 2) that corresponds to one of these alternative paths may be larger or smaller than the P-type doping concentration depicted in the graph, which in turn affects the width of the channel in the single crystal silicon. In certain semiconductor materials, it may be advantageous to know which path the N-type “poly” doping line takes through the semiconductor materials, so that the width of the channel may be more accurately determined. In addition, it may be advantageous to be able to control the path the “poly” line takes through the single crystal silicon so that the width of the channel itself might also be controlled.

When the N-type “poly” doping in the graph is created by diffusion, the path and the concentration of both the N-type and P-type doping throughout the single crystal silicon material can be difficult to predict and to manage. This uncertainty in turn makes it difficult to control the width of the P-type doping area, and thus the width and shape of the P-channel. Using an implanted gate as described in FIG. 1 instead of a diffusion process may allow more accurate control of the width of the P-type doping area. This may allow, for example, the P-type channel of a JFET device to be manufactured to a certain width or shape. This process may also allow the location of the intersection between the N-type doping and the P-type doping to be accurately controlled, leading to improvements in, for example, on-off ratio of the JFET.

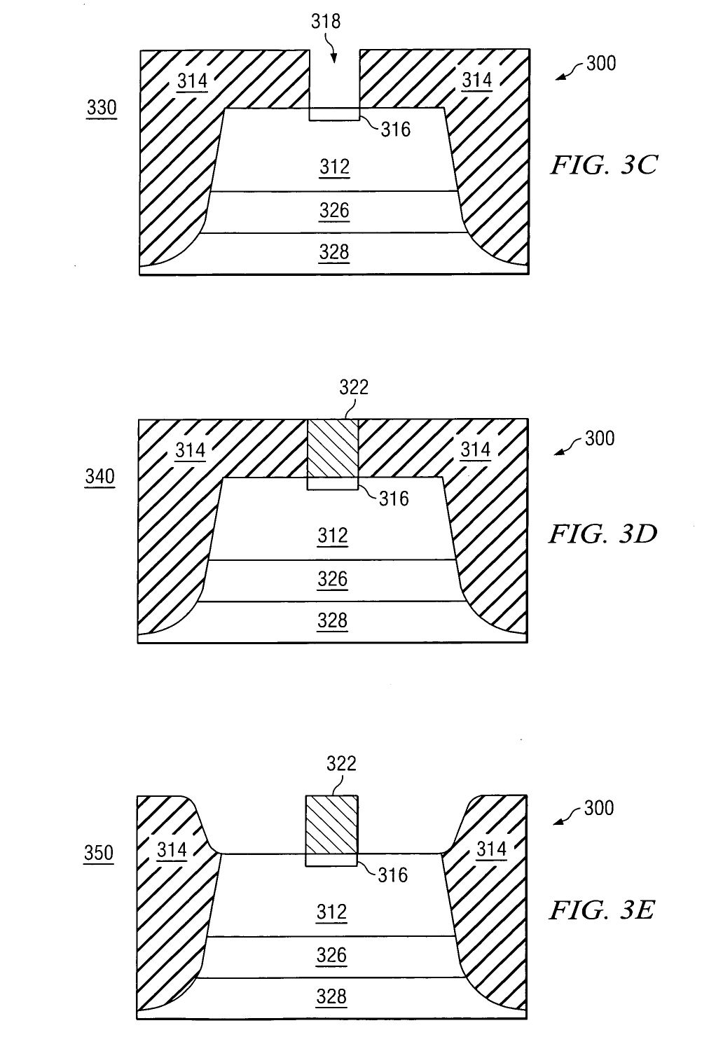

FIG. 3 illustrates an example method 300 of controlling a doping profile in a semiconductor. In particular, method 300 may allow the depth of the N-type doping in a P-type channel to be accurately controlled. The steps illustrated in FIG. 3 may be combined, modified, or deleted where appropriate. Additional steps may also be added to the example operation. Furthermore, the described steps may be performed in any suitable order. In step 310, a shallow trench isolation structure may be formed. Shallow trench isolation comprises etching a pattern of trenches in the silicon and depositing silicon dioxide to fill the trenches. The excess dielectric can then be removed with a technique such as planarization. Shallow trench isolation may be used in certain embodiments to prevent electrical current leakage between adjacent semiconductor device components. In step 310, channel 312 is comprised of any suitable semiconductor material for use as a transistor channel. In this example, channel 312 is a P-type doped channel. The well 326 is doped with N-type dopant and provides isolation between devices in combination with the STI. Well 326 may reside in a substrate 328.

Step 320 comprises depositing a layer of dielectric 314 on channel 312. The layer of dielectric 314 can be any suitable type of dielectric, such as silicon dioxide or silicon oxynitride. The thickness of the layer of dielectric 314 can vary due to chemical, mechanical, engineering, design, or manufacturing constraints or restrictions. Any suitable type or thickness of dielectric may be used, and any suitable method may be used to deposit, grow, or otherwise create the layer of dielectric 314 In step 330, a notch 318 is etched in the layer of dielectric 314. The layer of dielectric 314 is etched until notch 318 reaches channel 312. The location of notch 318 may vary but can be chosen, for example, to coincide with a location of a gate, source, or drain of a transistor. Once notch 318 has been etched in the layer of dielectric 314, doping 316 can be implanted in notch 318 to form a gate, source, or drain of a transistor. Doping 316 can be implanted by means of ion implantation into notch 318 and P-channel 312. Preferably, the method used to implant this N-type doping material allows the depth of the ion implantation in channel 312 to be controlled. This in turn may allow the vertical dimension of the P-doped area in P-channel 312 to be controlled, thus permitting a more precise manufacturing process for a semiconductor device. In step 330, the layer of dielectric 314 acts as a mask to other areas of channel 312 that do not require an implantation. Hence, the doped area 316 is self aligned with the subsequently formed contact 322. Once this gate implantation is complete, the process may move to step 340.

In step 340, polysilicon or metal 322 can be deposited into notch 318. Although not shown in step 340, polysilicon 322 may also be deposited on top of the layer of dielectric 314. At this point, in certain embodiments, polysilicon 322 in notch 318 can be doped with an N-type doping material. In other embodiments, polysilicon 322 and/or the layer of dielectric 314 may first be planarized using any suitable process, such as chemical mechanical planarization. Doping polysilicon 322 in notch 318 with an N-type doping material makes polysilicon 322 in notch 318 conductive. In certain embodiments, this is done to assist in the operation of the semiconductor device. In step 340, the layer of dielectric 314 may act as a mask to prevent N-type doping from reaching certain portions of channel 312.

In step 350, some or all of the layer of dielectric 314 may be etched or removed, using any suitable method for etching or otherwise removing dielectric. In certain embodiments, a source and/or drain of a transistor can now be created. The source and/or drain can be created by diffusing through a polysilicon layer (not shown) or using an ion implantation process as described above. Additional steps can then be performed to further prepare the semiconductor device for use as a transistor.

Although the present disclosure has been described with several embodiments, a myriad of changes, variations, alterations, transformations, and modifications may be suggested to one skilled in the art, and it is intended that the present disclosure encompass such changes, variations, alterations, transformations, and modifications as fall within the scope of the appended claims.

What is claimed is:

1. A method for fabricating a semiconductor device, comprising:
forming a channel of a transistor in a semiconductor substrate, wherein the channel has a first conductivity type;
depositing a layer of dielectric on at least a portion of the channel;
etching at least a notch in the layer of dielectric, wherein at least a portion of the notch is etched at least to the channel;
doping a portion of the channel that is exposed by the notch with material of a second conductivity type; and
filling the notch with a conductive material.

2. The method of claim 1, wherein the conductive material comprises polysilicon.

3. The method of claim 1, wherein doping a portion of the channel yields the portion of the channel being self-aligned with the notch.

4. The method of claim 1, wherein the conductive material comprises metal.

5. The method of claim 1, further comprising planarizing the conductive material and the layer of dielectric.

6. The method of claim 1, wherein doping the portion of the channel under the notch comprises doping with an ion implant.

7. The method of claim 1, wherein the doped portion of the channel under the notch comprises one of a gate region, a source region, or a drain region of a transistor.

8. The method of claim 1, wherein doping the portion of the channel under the notch comprises doping to a concentration of at least 1.0×10¹⁸ cm⁻³.

9. The method of claim 1, wherein doping the portion of the channel under the notch comprises producing a junction depth of less than 30 nanometers.

10. The method of claim 2, the method further comprising doping the polysilicon.

11. The method of claim 1, wherein a shallow trench isolation region is formed in the semiconductor substrate.

12. The method of claim 1, further comprising etching a second notch in the layer of dielectric, wherein at least a portion of the second notch is etched at least to the channel;
doping the portion of the channel that is exposed to the second notch with material of a first conductivity type; and
filling the second notch with a material.

13. The method of claim 12, wherein the material filling the second notch comprises polysilicon.

14. The method of claim 12, wherein the material filling the second notch comprises metal.

15. The method of claim 12, wherein the doped portion of the channel under the second notch comprises a source region of a transistor.

16. The method of claim 12, wherein the doped portion of the channel under the second notch comprises a drain region of a transistor.

17. The method of claim 12, wherein doping the portion of the channel under the second notch with material of a first conductivity type comprises doping with an ion implant.

18. The method of claim 1, wherein the semiconductor device comprises a Junction Field Effect transistor.

19. A method for fabricating a semiconductor device, comprising:
forming a channel of a transistor, wherein the channel has a first conductivity type;
depositing a layer of dielectric on at least a portion of the channel;
etching a first notch in the layer of dielectric, wherein at least a portion of the first notch is etched at least to the channel;
doping the portion of the channel that is exposed by the first notch with material of a second conductivity type;
etching a second notch in the layer of dielectric wherein at least a portion of the second notch is etched at least to the channel;
doping the portion of the channel that is exposed by the second notch;
etching a third notch in the layer of dielectric wherein at least a portion of the third notch is etched at least to the channel;
doping the portion of the channel that is exposed by the third notch; and
filling the first, the second, and the third notches with polysilicon.

20. The method of claim 19, wherein at least one of doping the portion of the channel under the first notch, doping the portion of the channel under the second notch, and doping the portion of the channel under the third notch comprises doping with an ion implant.

21. The method of claim 19, further comprising:
masking the first notch; and
doping the polysilicon in the second and third notches.

22. The method of claim 19, further comprising:
masking the second and third notches; and
doping the polysilicon in the first notch.

23. The method of claim 19, wherein the semiconductor device comprises a Junction Field Effect transistor.

24. A semiconductor device prepared by a process comprising the steps of:
forming a channel of a transistor, wherein the channel has a first conductivity type;
depositing a layer of dielectric on at least a portion of the channel;
etching a first notch in the layer of dielectric, wherein at least a portion of the first notch is etched at least to the channel; and
doping the portion of the channel that is exposed by the first notch with material of a second conductivity type.

25. The semiconductor device prepared by the process of claim 24, the process further comprising:
etching a second notch in the layer of dielectric wherein at least a portion of the second notch is etched at least to the channel;
doping the portion of the channel that is exposed under the second notch;
etching a third notch in the layer of dielectric wherein at least a portion of the third notch is etched at least to the channel;
doping the portion of the channel that is exposed under the third notch;
filling the first, the second, and the third notches with polysilicon;
masking the first notch; and
doping the polysilicon in the second and third notches.

26. The semiconductor device prepared by the process of claim 25, wherein at least one of doping the portion of the channel under the first notch, doping the portion of the channel under the second notch, and doping the portion of the channel under the third notch comprises doping with an ion implant.

27. The semiconductor device prepared by the process of claim 25, the process further comprising:
masking the second and third notches; and
doping the polysilicon deposited in the first notch.
